(19) United States
(12) Patent Application Publication
(10) Pub. No.: US 2026/0173599 A1
(43) Pub. Date: Jun. 18, 2026

(54) SELECTABLE-COLOR LIGHT-EMITTING DIODE CHIPS

(71) Applicant: CreeLED, Inc., Durham, NC (US)

(72) Inventors: Andre Pertuit, Raleigh, NC (US); Michael Check, Holly Springs, NC (US); Colin Blakely, Raleigh, NC (US); David Suich, Durham, NC (US); Joseph G. Sokol, Durham, NC (US); Robert Wilcox, Rolesville, NC (US)

(21) Appl. No.: 18/983,932

(22) Filed: Dec. 17, 2024

(51) Int. Cl. H10H 20/851; H10H 20/80; H10H 20/854; H10H 20/856

(52) U.S. Cl. CPC H10H 20/8516; H10H 20/8512; H10H 20/854; H10H 20/856; H10H 20/882

(57) ABSTRACT

Light-emitting diode (LED) devices, and more particularly selectable-color LED chips are disclosed. An exemplary LED chip includes arrangements of p-contacts and an n-contact for a continuous active LED structure that provides selectable injection of current. Various combinations of wavelength conversion elements may be positioned on different regions configured for selectable injection of current so that color mixing in aggregate emissions is controlled by selectively changing current injection across the various regions of the active LED structure. Exemplary LED chip structures and corresponding arrangements of wavelength conversion elements are disclosed for a variety of selectable-color applications.

### FIELD OF THE DISCLOSURE

The present disclosure relates to light-emitting diode (LED) devices, and more particularly to selectable-color LED chips.

### BACKGROUND

Light-emitting diodes (LEDs) are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions.

LEDs have been widely adopted in various illumination contexts, for backlighting of liquid crystal display (LCD) systems (e.g., as a substitute for cold cathode fluorescent lamps) and for direct-view LED displays. Applications utilizing LED arrays include vehicular headlamps, roadway illumination, light fixtures, and various indoor, outdoor, and specialty contexts.

LED packages have been developed that can provide mechanical support, electrical connections, and encapsulation for LED emitters. Lumiphoric materials, such as phosphors, may be arranged in light emission paths of LED emitters to convert portions of light to different wavelengths. Multiple-chip LED packages have been developed that include LED chips with different emission colors, some of which may include phosphor-converted emissions. Challenges exist in producing high quality light with desired emission characteristics and color mixing while also providing high light emission efficiency in LED devices.

The art continues to seek improved multiple-color LED devices with improved color mixing while overcoming limitations associated with conventional devices and production methods.

### SUMMARY

The present disclosure relates to light-emitting diode (LED) devices, and more particularly to selectable-color LED chips. An exemplary LED chip includes arrangements of p-contacts and an n-contact for a continuous active LED structure that provides selectable injection of current. Various combinations of wavelength conversion elements may be positioned on different regions configured for selectable injection of current so that color mixing in aggregate emissions is controlled by selectively changing current injection across the various regions of the active LED structure. Exemplary LED chip structures and corresponding arrangements of wavelength conversion elements are disclosed for a variety of selectable-color applications.

In one aspect, an LED chip comprises: an active LED structure comprising an n-type layer, a p-type layer, and an active layer that is between the n-type layer and the p-type layer; a first wavelength conversion element on a first region of the active LED structure; a second wavelength conversion element on a second region of the active LED structure, the active LED structure being continuous between the first region and the second region; a first p-contact on the first region of the active LED structure; a second p-contact on the second region of the active LED structure; and an n-contact on both the first region and the second region of the active LED structure. In certain embodiments, the first p-contact and the n-contact are configured to inject current directly into the first region and indirectly into the second region, and the second p-contact and the n-contact are configured to inject current directly into the second region and indirectly into the first region. The LED chip may further comprise: a third wavelength conversion element on a third region of the active LED structure, the active LED structure being continuous between the first region, the second region, and the third region; and a third p-contact on the third region, the third p-contact and the n-contact being configured to inject current directly into the third region. The LED chip may further comprise: a fourth wavelength conversion element on a fourth region of the active LED structure, the active LED structure being continuous between the first region, the second region, the third region, and the fourth region; and a fourth p-contact on the fourth region, the fourth p-contact and the n-contact being configured to inject current directly into the fourth region; wherein the first wavelength conversion element, the second wavelength conversion element, the third wavelength conversion element, and the fourth wavelength conversion element are configured to provide aggregate emissions with five distinct peak wavelengths. In certain embodiments, at least one portion of the active LED structure in the first region is devoid of any wavelength conversion element. In certain embodiments, the at least one portion of the active LED structure is covered by an encapsulant structure that is transparent to light emitted by the active LED structure. The LED chip may further comprise a light-absorbing material positioned between the first wavelength conversion element and the second wavelength conversion element. The LED chip may further comprise a light-reflective material positioned between the first wavelength conversion element and the second wavelength conversion element. The LED chip may further comprise a substrate on which the active LED structure is supported, wherein the first wavelength conversion element and the second wavelength conversion element are on a side of the substrate opposite the active LED structure. The LED chip may further comprise a carrier submount on which the active LED structure is supported, wherein the first p-contact is on an opposite side of the carrier submount relative to the n-contact. In certain embodiments, an area of the first wavelength conversion element on the active LED structure is less than an area of the second wavelength conversion element on the active LED structure. The LED chip may further comprise a light-scattering cover structure on the first wavelength conversion element and on the second wavelength conversion element. In certain embodiments, the first wavelength conversion element comprises a patterned or a textured surface. In certain embodiments, the first wavelength conversion element comprises a mixture of light-scattering particles and lumiphoric material particles. In certain embodiments, the first wavelength conversion element comprises at least one light-scattering coating. In certain embodiments, the first wavelength conversion element comprises a different thickness than the second wavelength conversion element.

In another aspect, an LED chip comprises: an active LED structure comprising an n-type layer, a p-type layer, and an active layer that is between the n-type layer and the p-type layer; a plurality of first wavelength conversion elements on the active LED structure; a first p-contact on a first region of the active LED structure; a second p-contact on a second region of the active LED structure, the active LED structure being continuous between the first region and the second region, and the plurality of first wavelength conversion elements being positioned on both the first region and the second region; and an n-contact on both the first region and the second region of the active LED structure. In certain embodiments, the first p-contact and the n-contact are configured to inject current directly into the first region and indirectly into the second region, and the second p-contact and the n-contact are configured to inject current directly into the second region and indirectly into the first region. In certain embodiments, each first wavelength conversion element of the plurality of first wavelength conversion elements is configured to convert a first peak wavelength of light from the active LED structure to a second peak wavelength that is different than the first peak wavelength. The LED chip may further comprise a plurality of second wavelength conversion elements on both the first region and the second region of the active LED structure, wherein each second wavelength conversion element of the plurality of second wavelength conversion elements is configured to convert the first peak wavelength of light from the active LED structure to a third peak wavelength that is different than the first peak wavelength and the second peak wavelength.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a top perspective view of a light-emitting diode (LED) chip structured to selectively emit multiple colors and combinations thereof according to principles of the present disclosure.

FIG. 1B is a top view of the LED chip of FIG. 1A.

FIG. 1C is a bottom view of the LED chip of FIGS. 1A and 1B.

FIG. 1D is a detailed cross-sectional view of the LED chip of FIGS. 1A to 1C taken along the sectional line 1D-1D of FIG. 1B.

FIG. 1E is a detailed cross-sectional view of the LED chip of FIGS. 1A to 1C taken along the sectional line 1E-1E of FIG. 1B.

FIG. 2 is a top perspective view of an LED chip similar to the LED chip of FIGS. 1A to 1E for embodiments where portions of the active LED structure are covered by an encapsulant structure that is devoid of lumiphoric materials.

FIG. 3A is a top view of an LED chip similar to the LED chip of FIGS. 1A to 1E for embodiments where a light-absorbing material is positioned to laterally separate various wavelength conversion elements.

FIG. 3B is a generalized cross-sectional view of the LED chip of FIG. 3A taken along the sectional line 3B-3B of FIG. 3A.

FIG. 4A is a top view of an LED chip similar to the LED chip of FIGS. 3A and 3B except a light-reflective material is positioned to laterally separate various wavelength conversion elements.

FIG. 4B is a generalized cross-sectional view of the LED chip of FIG. 4A taken along the sectional line 4B-4B of FIG. 4A.

FIG. 5A is a top view of an LED chip similar to the LED chip of FIGS. 1A to 1E except for embodiments with vertical chip structures.

FIG. 5B is a bottom view of the LED chip of FIG. 5A.

FIG. 5C is a generalized cross-sectional view of the LED chip of FIG. 5A taken along the sectional line 5C-5C of FIG. 5A.

FIG. 6 is a top view of an LED chip similar to the LED chip of FIGS. 1A to 1E for embodiments with four emission colors.

FIG. 7 is a top view of an LED chip similar to the LED chip of FIG. 6 for embodiments with three emission colors.

FIG. 8 is a top view of an LED chip similar to the LED chip of FIG. 6 for embodiments with more than four emission colors.

FIG. 9 is a top view of an LED chip similar to the LED chip of FIG. 7 except the area of the wavelength conversion elements and the encapsulant structures are varied to target different aggregate emissions.

FIG. 10 is a side view of an LED chip similar to the LED chip of FIGS. 1A to 1E for embodiments that further include a cover structure.

FIG. 11 is a side view of an LED chip similar to the LED chip of FIGS. 1A to 1E for embodiments where at least one of the wavelength conversion elements comprises a nonplanar surface.

FIG. 12 is a side view of an LED chip similar to the LED chip of FIGS. 1A to 1E for embodiments where at least one wavelength conversion element comprises light-scattering particles mixed with lumiphoric material particles.

FIG. 13 is a side view of an LED chip similar to the LED chip of FIG. 12 for embodiments where at least one wavelength conversion element includes at least one light-scattering coating.

FIG. 14 is a side view of an LED chip similar to the LED chip of FIGS. 1A to 1E for embodiments where at least one wavelength conversion element comprises a different thickness than the other wavelength conversion elements.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to selectable-color LED chips. An exemplary LED chip includes arrangements of p-contacts and an n-contact for a continuous active LED structure that provides selectable injection of current. Various combinations of wavelength conversion elements may be positioned on different regions configured for selectable injection of current so that color mixing in aggregate emissions is controlled by selectively changing current injection across the various regions of the active LED structure. Exemplary LED chip structures and corresponding arrangements of wavelength conversion elements are disclosed for a variety of selectable-color applications.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure may be fabricated from different material systems, with some material systems being Group III nitride-based material systems. Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon, aluminum nitride (AlN), and GaN.

The active LED structure may be configured to emit different wavelengths of light depending on the composition of the active LED structure. For example, the active LED structure may emit blue light with a peak wavelength range of approximately 430 nanometers (nm) to 480 nm, or green light with a peak wavelength range of 500 nm to 570 nm, or red light with a peak wavelength range of 600 nm to 700 nm. In certain embodiments, the active LED structure may be configured to emit light that is outside the visible spectrum, including one or more portions of the ultraviolet (UV) spectrum (e.g., 100 nm to 400 nm), or one or more portions of the near infrared spectrum, and/or the infrared spectrum (e.g., 700 nm to 1000 nm).

One or more portions of an LED chip may also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2500 Kelvin (K) to 10,000 K. In certain embodiments, lumiphoric materials having cyan, green, amber, yellow, orange, and/or red peak wavelengths may be used. In certain embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof. In other embodiments, the LED chip and corresponding lumiphoric material may be configured to primarily emit converted light from the lumiphoric material so that aggregate emissions include little to no perceivable emissions that correspond to the LED chip itself.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material. In certain embodiments, a top surface of an LED chip may include lumiphoric material, while one or more side surfaces of an LED chip may be devoid of lumiphoric material. In certain embodiments, all or substantially all outer surfaces of an LED chip (e.g., other than contact-defining or mounting surfaces) may be coated or otherwise covered with one or more lumiphoric materials. In certain embodiments, one or more lumiphoric materials may be arranged on or over one or more surfaces of an LED chip in a substantially uniform manner. In other embodiments, one or more lumiphoric materials may be arranged on or over one or more surfaces of an LED chip in a manner that is non-uniform with respect to one or more of material composition, concentration, and thickness. In certain embodiments, the loading percentage of one or more lumiphoric materials may be varied on or among one or more outer surfaces of an LED chip. In certain embodiments, one or more lumiphoric materials may be patterned on portions of one or more surfaces of an LED chip to include one or more stripes, dots, curves, or polygonal shapes. In certain embodiments, multiple lumiphoric materials may be arranged in different discrete regions or discrete layers on or over an LED chip.

In certain embodiments, one or more lumiphoric materials may be provided as at least a portion of a wavelength conversion element or cover structure that is provided over an LED chip. Wavelength conversion elements or cover structures may include a support element and one or more lumiphoric materials that are provided by any suitable means, such as by coating a surface of the support element or by incorporating the lumiphoric materials within the support element. In some embodiments, the support element may be composed of a transparent material, a semi-transparent material, or a light-transmissive material, such as sapphire, SiC, silicone, and/or glass (e.g., borosilicate and/or fused quartz). Wavelength conversion elements and cover structures may also include ceramic phosphor plates, phosphor-in-glass structures, and/or single crystal phosphors.

Wavelength conversion elements and cover structures of the present disclosure may be formed from a bulk material which is optionally patterned and then singulated. In certain embodiments, the patterning may be performed by an etching process (e.g., wet or dry etching), or by another process that otherwise alters a surface, such as with a laser or saw. In certain embodiments, wavelength conversion elements and cover structures may be thinned before or after the patterning process is performed. In certain embodiments, wavelength conversion elements and cover structures may comprise a generally planar upper surface that corresponds to a light emission area of the LED package. Phosphor-in-glass or ceramic phosphor plate arrangements may be formed by mixing phosphor particles with glass frit or ceramic materials, pressing the mixture into planar shapes, and firing or sintering the mixture to form a hardened structure that can be cut or separated into individual wavelength conversion elements. Wavelength conversion elements and cover structures may be attached to one or more LED chips using, for example, a layer of transparent adhesive. In certain embodiments, the layer of the transparent adhesive may include silicone with a refractive index in a range of about 1.3 to about 1.6 that is less than a refractive index of the LED chip on which the wavelength conversion element is placed.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In certain embodiments, a “light-transmissive” material may be configured to transmit at least 50% of emitted radiation of a desired wavelength.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED chips as described herein may be configured for mounting within LED packages. Such LED packages may include one or more elements, such as lumiphoric materials, encapsulants, light-altering materials, lenses, and electrical contacts, among others that are provided with one or more LED chips. In certain aspects, an LED package may include a support structure or support member, such as a submount or a lead frame. Suitable materials for the submount include, but are not limited to, ceramic materials such as aluminum oxide or alumina, AlN, or organic insulators like polyimide (PI) and polyphthalamide (PPA). In other embodiments, a submount may comprise a printed circuit board (PCB), sapphire, Si or any other suitable material. For PCB embodiments, different PCB types can be used such as standard FR-4 PCB, metal core PCB, or any other type of PCB. Light-altering materials may be arranged within LED packages to reflect or otherwise redirect light from the one or more LED chips in a desired emission direction or pattern.

As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast.

For some applications, multiple-chip LED packages have been developed that include LED chips emitting different colors, such as red-green-blue or red-green-blue-white arrangements. Such LED packages are adept at providing various combinations of colors of light by being able to selectively turn on and off LED chips independently of one another. Challenges exist in effectively mixing light from multiple-color LED chips within a common package and/or under a common lens. LED chips are typically arranged as close to one another as possible to improve mixing, but practical limitations exist related to separately mounting and electrically coupling multiple LED chips in close proximity to one another. Additionally, the use of secondary optics and/or diffusers may still be required to improve color mixing.

According to aspects of the present disclosure, a single LED chip is configured with multiple wavelength conversion elements laterally spaced across a light-emitting surface of the LED chip. The LED chip is further structured so that individually addressable regions of the overall active LED structure are provided that correspond with different ones or groupings of wavelength conversion elements. The active LED structure may form a continuous structure such the active layer is not subdivided into multiple junctions. By selectively injecting current into portions of the active LED structure that are vertically registered with different wavelength conversion elements, the single LED chip is capable of emitting various combinations of colors based on where current is injected. Moreover, the use of a single LED chip with a single active LED structure and associated single p-n junction reduces and/or eliminates spacing requirements needed for different colored emitting regions associated with conventional multiple-chip configurations and/or segregation of multiple-junction LED chip configurations.

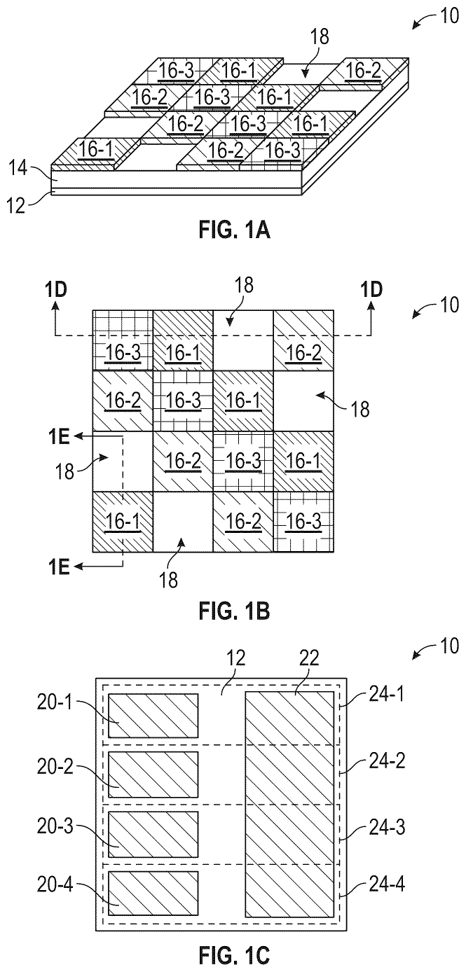

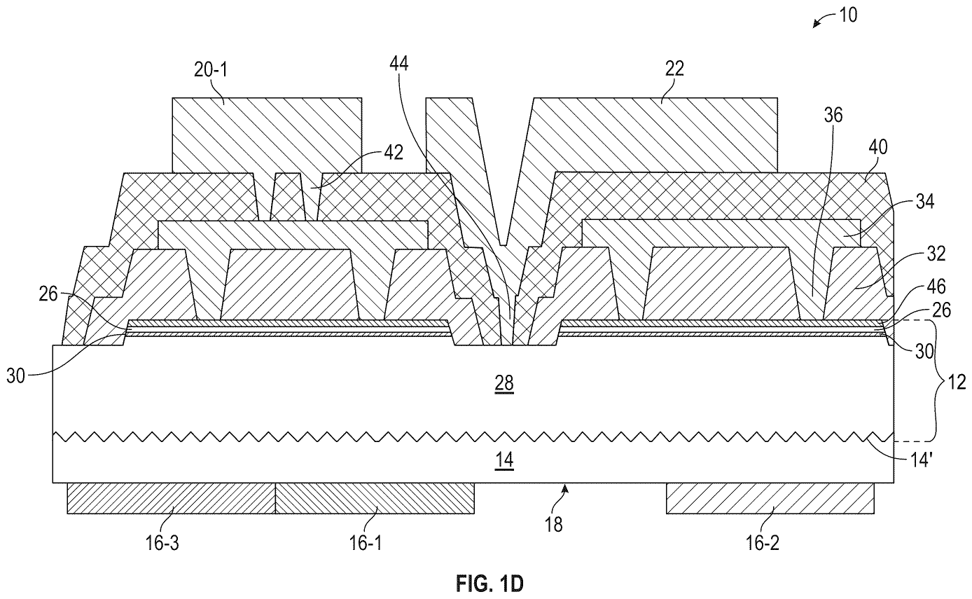

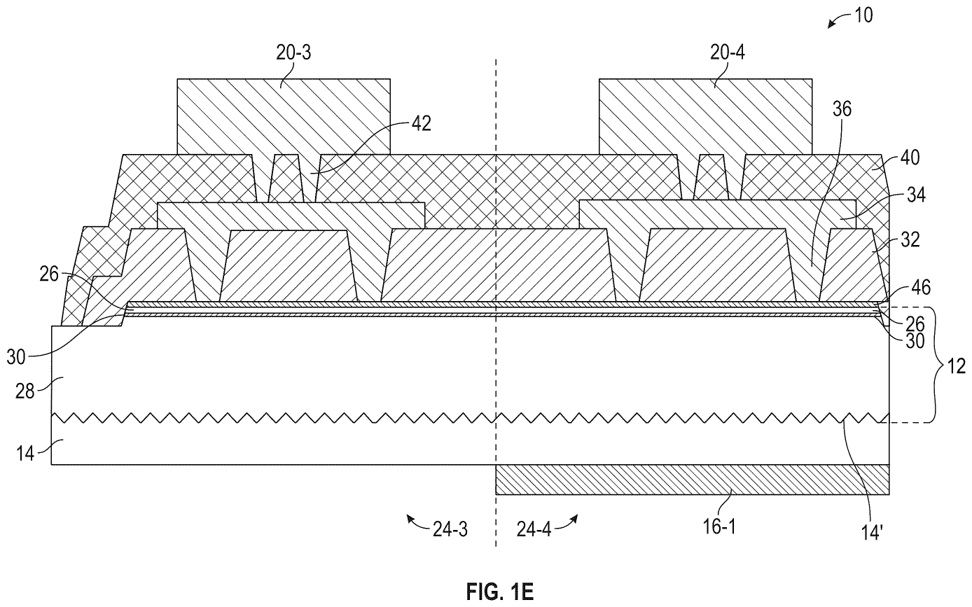

FIG. 1A is a top perspective view of an LED chip 10 structured to selectively emit multiple colors and combinations thereof according to principles of the present disclosure. FIG. 1B is a top view of the LED chip 10 of FIG. 1A. The LED chip 10 includes an active LED structure 12 configured to generate light when electrically activated. As described above, the active LED structure is typically an epitaxial layer structure including one or more n-type layers, an active layer, and one or more p-type layers. In certain embodiments, the active LED structure 12 is supported by a substrate 14, such as growth substrate, on which the active LED structure 12 is formed. In the context of GaN-based layers for the active LED structure 12, the substrate 14 may comprise sapphire, among other options, that is light-transmissive and/or light-transparent to light generated by the active LED structure 12. Accordingly, light from the active LED structure 12 may freely pass through the substrate 14 in a desired emission direction, particularly for flip-chip embodiments where the substrate 14 is positioned above the active LED structure 12 as illustrated in FIG. 1A. In other embodiments, the substrate 14 may be removed after growth of the active LED structure 12.

As illustrated in FIGS. 1A and 1B, the LED chip 10 further includes a number of wavelength conversion elements 16-1 to 16-3 positioned to receive light from various regions of the active LED structure 12. Each of the wavelength conversion elements 16-1 to 16-3 may comprise lumiphoric materials and/or lumiphoric material layers configured to convert portions of light from the active LED structure 12 to different wavelengths. As described above, exemplary structures for the wavelength conversion elements 16-1 to 16-3 include lumiphoric material layers on support elements, ceramic phosphor plates, phosphor-in-glass structures, and/or single crystal phosphors. In certain embodiments, the wavelength conversion elements 16-1 to 16-3 comprise lumiphoric material layers that are coated or otherwise deposited on the substrate 14.

For multiple color applications, the wavelength conversion elements 16-1 to 16-3 may be configured to provide different wavelengths by way of wavelength conversion. For example, first wavelength conversion elements 16-1 may be configured to convert light of a first peak wavelength, such as in a blue wavelength range, from the active LED structure 12 to light with a second peak wavelength, such as in a yellow wavelength range. Second wavelength conversion elements 16-2 may be configured to convert the light from the active LED structure 12 to light with a third peak wavelength, such as in a green wavelength range, and third wavelength conversion elements 16-3 may be configured to convert light from the active LED structure 12 to light with a fourth peak wavelength, such as in a red wavelength range. Accordingly, the LED chip 10 is capable of providing aggregate emissions that include the first, second, third, and fourth peak wavelengths.

In certain embodiments, positioning of the wavelength conversion elements 16-1 to 16-3 may be scattered across different regions of the active LED structure so that different colored emissions may be effectively mixed in aggregate emissions. As described above, conventional devices with separate LED chips or separate LED junctions require certain spacing structures for segregation that may adversely impact color mixing. Since there are no boundaries segregating different regions of the active LED structure 12 that are vertically registered with different wavelength conversion elements, light mixing may be improved in the LED chip 10. When the active LED structure 12 is electrically activated, light of the first peak wavelength may be provided across substantially all of the area of the active LED structure 12, while each wavelength conversion element 16-1 to 16-3 may provide a mixture of the second, third, and fourth peak wavelengths. In certain embodiments, various portions 18 of the active LED structure 12 may be devoid of any wavelength conversion elements 16-1 to 16-3 so that a majority of light from the active LED structure 12 passing through these portions 18 escapes the LED chip 10 without wavelength conversion. Such portions 18 may also be scattered across the LED chip 10 for enhanced light mixing.

FIG. 1C is a bottom view of the LED chip 10 of FIGS. 1A and 1B. The LED chip 10 may include multiple p-contacts 20-1 to 20-4 and an n-contact 22. The p-contacts 20-1 to 20-4 are positioned to inject current into different regions of the active LED structure 12. For illustrative purposes, different regions 24-1 to 24-4 are illustrated with superimposed dashed-line boxes. In certain embodiments, the n-contact 22 may be common for the p-contacts 20-1 to 20-4. In other embodiments, the n-contact 22 may be subdivided in a similar manner as the p-contacts 20-1 to 20-4. In either case, the LED chip 10 is configured with individually addressable current injection regions by way of the separate p-contacts 20-1 to 20-4. Since the active LED structure 12 is continuous across the LED chip 10, current may laterally spread to adjacent regions. For example, selectively injecting current by way of only the p-contact 20-1 will provide highest current injection along direct electrically conductive paths within a first region 24-1 of the active LED structure 12 that is between the p-contact 20-1 and the n-contact 22. Light generation in the first region 24-1 of the active LED structure 12 will be highest, thereby providing highest amounts of wavelength conversion from the corresponding wavelength conversion elements 16-1 to 16-3 of FIG. 1B that are on the first region 24-1. Some current may spread laterally to other regions 24-2 to 24-4 of the active LED structure 12 defined between corresponding ones of the p-contacts 20-2 to 20-4 and the n-contact 22. While highest light generation will be provided along the first region 24-1, some lateral spreading may generate smaller amounts of light in one or more of the other regions 24-2 to 24-4, thereby enhancing color mixing in aggregate emissions. The ability to selectively control which portions of the active LED structure 12 have highest current injection thereby provides selective control over which combination of wavelength conversion elements 16-1 to 16-3 and/or uncovered portions 18 contribute to higher amounts of light in aggregate emissions from the LED chip 10. Accordingly, a single p-n junction of the active LED structure 12 may be selectively addressed across various regions 24-1 to 24-4 to selectively control various colors of aggregate emissions from the LED chip 10.

FIG. 1D is a detailed cross-sectional view of the LED chip 10 of FIGS. 1A to 1C taken along the sectional line 1D-1D of FIG. 1B. Accordingly, FIG. 1D is from the perspective of the first region 24-1 of FIG. 1C. The active LED structure 12 includes at least a p-type layer 26, an n-type layer 28, and an active layer 30 therebetween. The active LED structure 12 is formed on the substrate 14. In certain embodiments, one or more buffer layers and/or undoped layers may be provided between the substrate 14 and n-type layer 28 of the active LED structure 12. In certain embodiments, the n-type layer 28 is between the active layer 30 and the substrate 14. In other embodiments, the doping order may be reversed. The substrate 14 may comprise various light-transmissive and/or light-transparent materials such as sapphire and may have one or more surfaces that are shaped, textured, or patterned to enhance light extraction. In certain embodiments, the substrate 14 may include a patterned surface 14′ that is proximate the active LED structure 12 and includes multiple recessed and/or raised features.

In FIG. 1D, a dielectric reflective layer 32 is provided on portions of the p-type layer 26. The dielectric reflective layer 32 may comprise many different materials and preferably comprises a material that presents an index of refraction step with the material of the active LED structure 12 to promote total internal reflection (TIR) of light generated from the active LED structure 12. Light that experiences TIR is redirected without experiencing absorption or loss and can thereby contribute to useful or desired LED chip emission. In certain embodiments, the dielectric reflective layer 32 comprises silicon dioxide (SiO₂) and/or silicon nitride (SiN). It is understood that many dielectric materials can be used such as SiN, SiNx, Si₃N₄, Si, germanium (Ge), SiO₂, SiOx, titanium oxide (TiOₓ) titanium dioxide (TiO₂), tantalum pentoxide (Ta₂O₅), indium tin oxide (ITO), magnesium oxide (MgOx), zinc oxide (ZnO), and combinations thereof. In certain embodiments, the dielectric reflective layer 32 comprises multiple alternating layers of different dielectric materials, e.g., alternating layers of SiO₂ and TiOₓ that symmetrically repeat or are asymmetrically arranged to form an asymmetric distributed Bragg reflector. Portions of the dielectric reflective layer 32 may extend along mesa sidewalls of the active LED structure 12 and along sidewall portions of the p-type layer 26, the active layer 30, and the n-type layer 28.

The LED chip 10 may further include a metal reflective layer 34 that is on the dielectric reflective layer 32 such that the dielectric reflective layer 32 is arranged between the active LED structure 12 and the metal reflective layer 34. The metal reflective layer 34 forms a structure configured to reflect any light from the active LED structure 12 that may pass through the dielectric reflective layer 32. According to aspects of the present disclosure, the metal reflective layer 34 may comprise first and second metals with varying concentrations that promote high reflectivity while also providing improved mechanical stability, improved adhesion, and reduced electromigration. Exemplary materials for the first and second metals include different ones of silver (Ag), indium (In), tin (Sn), zinc (Zn), or tin-silver-copper (SAC). As illustrated, the metal reflective layer 34 may include one or more reflective layer interconnects 36 that provide electrically conductive paths through the dielectric reflective layer 32 to the p-type layer 26. In certain embodiments, the reflective layer interconnects 36 comprise reflective layer vias. In certain embodiments, the reflective layer interconnects 36 comprise the same material as the metal reflective layer 34 and are formed at the same time as the metal reflective layer 34. In other embodiments, the reflective layer interconnects 36 may comprise a different material than the metal reflective layer 34.

A passivation layer 40 may be included on the metal reflective layer 34 and on portions of the dielectric reflective layer 32 that are uncovered by the metal reflective layer 34. The passivation layer 40 protects and provides electrical insulation for the LED chip 10 and may comprise many different materials, such as a dielectric material. In certain embodiments, the passivation layer 40 is a single layer, and in other embodiments, the passivation layer 40 comprises a plurality of layers. A suitable material for the passivation layer 40 includes but is not limited to SiN, SiNx, and/or Si₃N₄. In certain embodiments, the dielectric reflective layer 32 comprises SiO₂ and the passivation layer 40 comprises SiN, SiNx, or Si₃N₄. In other embodiments, the dielectric reflective layer 32 and at least a portion of the passivation layer 40 may each comprise SiO₂. As illustrated, the dielectric reflective layer 32 may bound perimeter and/or sidewall portions of the active LED structure 12 along a perimeter of the LED chip 10. Furthermore, the passivation layer 40 may be arranged to also bound perimeter portions of the active LED structure 12. In this manner, portions of the dielectric reflective layer 32 may be arranged between portions of the passivation layer 40 along sidewalls of the active LED structure 12 for enhanced passivation and protection.

In the cross-sectional view of FIG. 1D, the p-contact 20-1 and the n-contact 22 are visible. As illustrated, the p-contact 20-1 and the n-contact 22 are arranged on the passivation layer 40 and are configured to provide electrical connections with the active LED structure 12. It is appreciated that the description of the p-contact 20-1 is equally applicable to the other p-contacts 20-2 to 20-4 of FIG. 1C for different regions of the LED chip 10. The p-contact 20-1, which may also be referred to as an anode contact, may comprise one or more p-contact interconnects 42 that extend through the passivation layer 40 to provide an electrical path to the p-type layer 26 that includes the metal reflective layer 34. In certain embodiments, the one or more p-contact interconnects 42 comprise one or more p-contact vias. The n-contact 22, which may also be referred to as a cathode contact, is electrically coupled to the n-type layer 28 by way of one or more n-contact interconnects 44 that extend through the passivation layer 40, the dielectric reflective layer 32, the metal reflective layer 34, the p-type layer 26, and the active layer 30. In certain embodiments, the one or more n-contact interconnects 44 may be referred to as one or more n-contact vias. Openings for the n-contact interconnects 44 may be formed in various etching steps. For illustrative purposes, FIG. 1D is shown with a single n-contact interconnect 40. In practice, the LED chip 10 may include multiple n-contact interconnects 40 spaced apart in an array pattern across the active LED structure 12. It is appreciated that the n-contact interconnect 44 forms a relatively small opening through portions of the active LED structure 12 and that the active layer 30 and the p-type layer 26 are continuous around the lateral portions of the n-contact interconnect 44 out of a plane of view for the cross-section of FIG. 1D.

In certain embodiments, a current spreading layer 46 may be provided between the p-type layer 26 and the dielectric reflective layer 32. The current spreading layer 46 may include a thin layer of a transparent conductive oxide such as indium tin oxide (ITO) or a thin metal layer such as platinum (Pt), although other materials may be used. As illustrated, the one or more reflective layer interconnects 36 may contact the current spreading layer 46 to provide electrically conductive pathways to the active LED structure 12.

The p-contact 20-1 and the n-contact 22 may comprise many different materials such as gold (Au), copper (Cu), nickel (Ni), In, aluminum (Al), Ag, Sn, Pt, or combinations thereof. In still other embodiments, the p-contact 20-1 and the n-contact 22 may comprise conducting oxides and transparent conducting oxides such as ITO, nickel oxide (NiO), ZnO, cadmium tin oxide, indium oxide, tin oxide, magnesium oxide, ZnGa₂O₄, ZnO₂/Sb, Ga₂O₃/Sn, AgInO₂/Sn, In₂O₃/Zn, CuAlO₂, LaCuOS, CuGaO₂, and SrCu₂O₂. The choice of material used can depend on the location of the contacts and on the desired electrical characteristics, such as transparency, junction resistivity, and sheet resistance. In certain embodiments, the LED chip 10 is arranged for flip-chip mounting and the p-contact 20-1 and n-contact 22 are configured to be mounted or bonded to a surface, such as a printed circuit board. While FIG. 1D is described in the context of a flip-chip structure, the principles disclosed are readily applicable to other chip structures.

In operation, a signal applied across the p-contact 20-1 and the n-contact 22 is conducted to the p-type layer 26 and the n-type layer 28, causing the LED chip 10 to emit light from the active layer 30. With reference to FIGS. 1C and 1D, applying a signal to the p-contact 20-1 and the n-contact 22 will result in increased current injection in the first region 24-1 of the active LED structure 12 relative to the other regions 24-2 to 24-4. Accordingly, the specific wavelength conversion elements 16-1, 16-2, and 16-3 that are vertically registered with the first region 24-1 will receive increased light and contribute to increased wavelength conversion. Furthermore, the portion 18 of the active LED structure 12 that is devoid of wavelength conversion elements and vertically registered with the first region 24-1 may pass increased amounts of unconverted light from the active LED structure 12. With reference to FIGS. 1B and 1C, selectively applying signals between the n-contact 22 and different ones or combinations of the p-contacts 20-1 to 20-4 will thereby provide different aggregate emission colors based on which combination of wavelength conversion elements 16-1 to 16-3 and uncovered portions 18 provide increased light. Moreover, the aggregate emissions have enhanced color mixing due to the continuous nature of the active LED structure 12 by avoiding physical segregation between emitting region associated with conventional multiple-chip and/or multiple-junction devices.

FIG. 1E is a detailed cross-sectional view of the LED chip 10 of FIGS. 1A to 1C taken along the sectional line 1E-1E of FIG. 1B. The view of FIG. 1E illustrates portions of the active LED structure 12 that extend between third and fourth regions 24-3, 24-4 of the active LED structure 12. For illustrative purposes, a superimposed vertical dashed line is provided to designate the third and fourth regions 24-3, 24-4 of the active LED structure 12. As illustrated, the active LED structure 12, including the active layer 30 and the p-type layer 26, is continuous between the regions 24-3, 24-4. When a signal is applied to the p-contact 20-3, current is directly injected into the third region 24-3, while some lateral current spreading may indirectly inject smaller amounts of current into the fourth region 24-4. In a similar manner, when a signal is applied to the p-contact 20-4, current is directly injected into the fourth region 24-4, while some lateral current spreading may indirectly inject smaller amounts of current into the third region 24-3. The separate p-contacts 20-1 to 20-4 of the LED chip 10 of FIGS. 1A to 1E provides the ability to separately control current injection levels across the various regions 24-1 to 24-4 of the active LED structure 12.

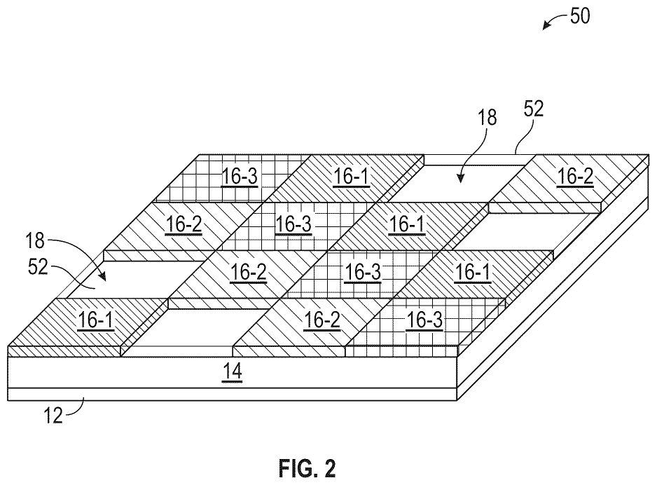

FIG. 2 is a top perspective view of an LED chip 50 similar to the LED chip 10 of FIGS. 1A to 1E for embodiments where the portions 18 of the active LED structure 12 are covered by an encapsulant structure 52 that is devoid of lumiphoric materials. The encapsulant structure 52 is configured to be light-transmissive and/or light-transparent to light generated by the active LED structure 12, thereby allowing such light to pass freely through these portions 18 and escape the LED chip 50 as unconverted light. Moreover, the encapsulant structure 52 may be light-transmissive and/or light-transparent to wavelength-converted light provided the wavelength conversion elements 16-1 to 16-3. In certain embodiments, the encapsulant structure 52 comprises silicone, glass, or the like. The encapsulant structure 52 may be formed on the LED chip 50, or the encapsulant structure 52 may represent a pre-formed cover structure that is separately formed and then attached to the LED chip 50.

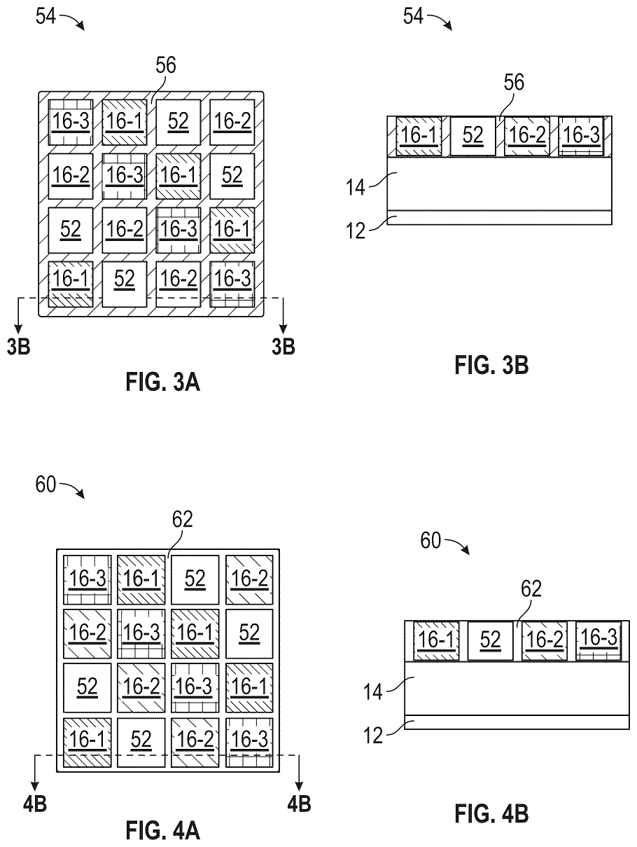

FIG. 3A is a top view of an LED chip 54 similar to the LED chip 10 of FIGS. 1A to 1E for embodiments where a light-absorbing material 56 is positioned to laterally separate various wavelength conversion elements 16-1 to 16-3. As illustrated, the light-absorbing material 56 may be positioned to laterally surround perimeter edges of one or more of the wavelength conversion elements 16-1 to 16-3 and/or the encapsulant structures 52. By positioning the light-absorbing material 56 in this manner, increased contrast is provided between different color producing areas of the LED chip 54. The light-absorbing material 56 may embody a light-altering material that includes at least one of carbon, silicon, or metal particles or nanoparticles suspended in an electrically insulating binder, such as silicone or epoxy. In certain embodiments, the light-absorbing material 56 may comprise a generally opaque or black color for absorbing light and increasing contrast.

FIG. 3B is a generalized cross-sectional view of the LED chip 54 of FIG. 3A taken along the sectional line 3B-3B of FIG. 3A. As illustrated, the light-absorbing material 56 may be positioned between adjacent wavelength conversion elements 16-1 to 16-3 and/or the encapsulant structures 52. As such, the light-absorbing material 56 may form lateral segregation elements on substrate 14. In certain embodiments, the light-absorbing material 56 may be dispensed or otherwise formed on the substrate 14 and between adjacent wavelength conversion elements 16-1 to 16-3 and/or the encapsulant structures 52. In other embodiments, the entire structure of the wavelength conversion elements 16-1 to 16-3, the encapsulant structures 52, and the light-absorbing material 56 may embody a pre-formed structure that is subsequently attached to the substrate 14.

FIG. 4A is a top view of an LED chip 60 similar to the LED chip 54 of FIGS. 3A and 3B except a light-reflective material 62 is positioned to laterally separate various wavelength conversion elements 16-1 to 16-3. FIG. 4B is a generalized cross-sectional view of the LED chip 60 of FIG. 4A taken along the sectional line 4B-4B of FIG. 4A. As illustrated, the light-reflective material 62 may be positioned to laterally surround perimeter edges of one or more of the wavelength conversion elements 16-1 to 16-3 and/or the encapsulant structures 52. By positioning the light-reflective material 62 in this manner, increased reflectivity and light extraction may be provided between different color producing areas of the LED chip 60. The light-reflective material 62 may embody a light-altering material that includes at least one of fused silica, fumed silica, TiO₂, or metal particles or nanoparticles suspended in an electrically insulating binder, such as silicone or epoxy. In certain embodiments, the light-altering material may comprise a generally white color to reflect and redirect light.

While the previous embodiments have been described in the context of flip-chip structures where the n-contact 22 and the p-contacts 20-1 to 20-4 are on a same side of active LED structures 12, the principles described are applicable to other chip structures. As will be described below in greater detail, the principles described are applicable to vertical contact LED chip structures where the n-contact 22 and the p-contacts 20-1 to 20-4 are on opposing sides of LED chip.

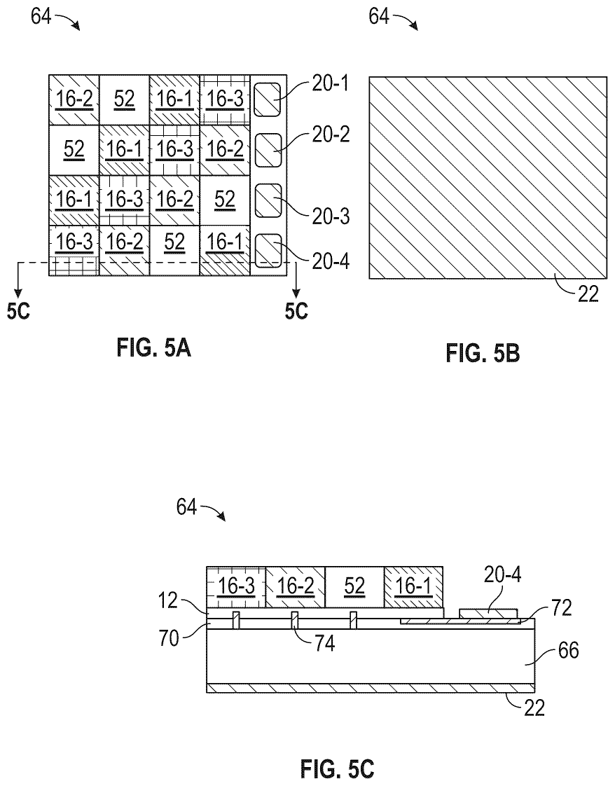

FIG. 5A is a top view of an LED chip 64 similar to the LED chip 10 of FIGS. 1A to 1E except for embodiments with vertical chip structures. FIG. 5B is a bottom view of the LED chip 64 of FIG. 5A. As illustrated in FIG. 5A, the p-contacts 20-1 to 20-4 are positioned accessible from the top side of the LED chip 64 in positions laterally spaced from the wavelength conversion elements 16-1 to 16-3 and the encapsulant structures 52. As illustrated in FIG. 5B, the n-contact 22 may reside on a bottom side or mounting side of the LED chip 64. The LED chip 64 is configured for mounting and electrically coupling the n-contact 22 to another surface, and electrical connections to the p-contacts 20-1 to 20-4 may be made by way of wire bonds from the top side. In such embodiments, the substrate 14 of FIG. 1 may be removed if it comprises insulating materials such as sapphire.

FIG. 5C is a generalized cross-sectional view of the LED chip 64 of FIG. 5A taken along the sectional line 5C-5C of FIG. 5A. The growth substrate 14 of FIG. 1A may be replaced by a carrier submount 66 that forms a part of electrical pathways to the active LED structure 12. In certain embodiments, one or more passivation layers 70 may be arranged between the carrier submount 66 and the active LED structure 12 to avoid electrical shorting between the p-contacts 20-1 to 20-4 and the n-contact 22. As illustrated in FIG. 5C, the p-contact 20-4 is coupled to the active LED structure 12 by way of an electrically conductive path 72, and the n-contact 22 is electrically coupled to the active LED structure 12 by way of one or more separate electrically conductive paths 74.

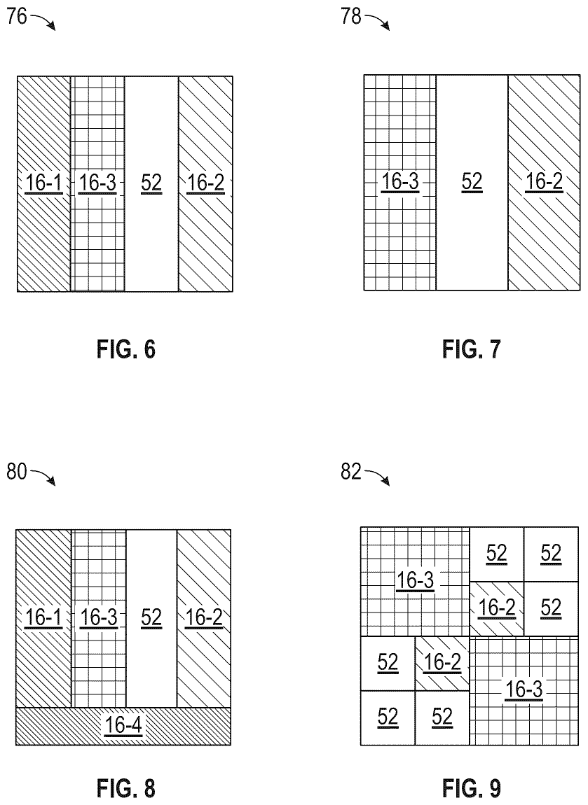

According to principles of the present disclosure, wavelength conversion structures may form various shapes and sizes on corresponding LED chips. The various shapes, sizes, and wavelength-conversion colors may be readily tailored to various applications without added complexity due to the nature of single junction LED chips as described herein. FIGS. 6 to 14 provide various examples that may be implemented, depending on the desired level of color changing and mixing.

FIG. 6 is a top view of an LED chip 76 similar to the LED chip 10 of FIGS. 1A to 1E for embodiments with four emission colors or peak wavelengths. By way of example, the first wavelength conversion element 16-1 may covert a portion of light to yellow wavelengths, the second wavelength conversion element 16-2 may convert a portion of light to green wavelengths, and the third wavelength conversion element 16-3 may convert a portion of light to red wavelengths. The active LED structure of the LED chip 76 may emit light with blue wavelengths, a portion of which may be subject to wavelength conversion by the wavelength conversion elements 16-1 to 16-3. Additionally, blue light may readily pass through the encapsulant structure 52 that is devoid of lumiphoric materials. In certain embodiments, the different regions 24-1 to 24-4 of the active layer structure 12 as illustrated in FIG. 1C may correspond with separate ones of the wavelength conversion elements 16-1 to 16-3 and the encapsulant structure 52 so that selective injection of current may effectively control color combinations of four distinct peak wavelengths in aggregate emissions.

FIG. 7 is a top view of an LED chip 78 similar to the LED chip 76 of FIG. 6 for embodiments with three emission colors. For example, the first wavelength conversion element 16-1 of FIG. 6 may be omitted in the LED chip 78. By way of example, the LED chip 78 may be structured with selectable current injection regions that correspond to red, green, and blue colors in aggregate emissions. In certain embodiments, different regions 24-1 to 24-3 of the active layer structure 12 as illustrated in FIG. 1C may correspond with separate ones of the wavelength conversion elements 16-3, 16-2 and the encapsulant structure 52 so that selective injection of current may effectively control color combinations of three distinct peak wavelengths in aggregate emissions.

FIG. 8 is a top view of an LED chip 80 similar to the LED chip 76 of FIG. 6 for embodiments with more than four emission colors. By way of example, the LED chip 76 includes a fourth wavelength conversion element 16-4 that corresponds to another selectable current injection region. In certain embodiments, the fourth wavelength conversion element 16-4 may be configured to convert light to a wavelength that is between other wavelengths of light for increased color gamut. In one example, the fourth wavelength conversion element 16-4 provides cyan wavelengths that fill portions of the emission spectrum between the blue and green wavelengths. In certain embodiments, the different regions 24-1 to 24-4 of the active layer structure 12 as illustrated in FIG. 1C may correspond with separate ones of the wavelength conversion elements 16-1 to 16-4 and the encapsulant structure 52 so that selective injection of current may effectively control color combinations of five distinct peak wavelengths in aggregate emissions.

FIG. 9 is a top view of an LED chip 82 similar to the LED chip 78 of FIG. 7 except the area of the wavelength conversion elements 16-2, 16-3 and the encapsulant structures 52 are varied to target different aggregate emissions. By way of example, the third wavelength conversion elements 16-3 have larger areas than the second wavelength elements 16-2 and the encapsulant structure 52. Accordingly, increased light from the third wavelength conversion elements 16-3 may be provided in aggregate emissions. In a specific embodiment, the second wavelength conversion element 16-2 may be configured to provide green light, which has highest sensitivity with the human eye. Accordingly, the overall area of the second wavelength conversion elements 16-2 may be smaller than that of either the encapsulant structures 52 and the third wavelength conversion elements 16-3 for enhanced color balancing in aggregate emissions.

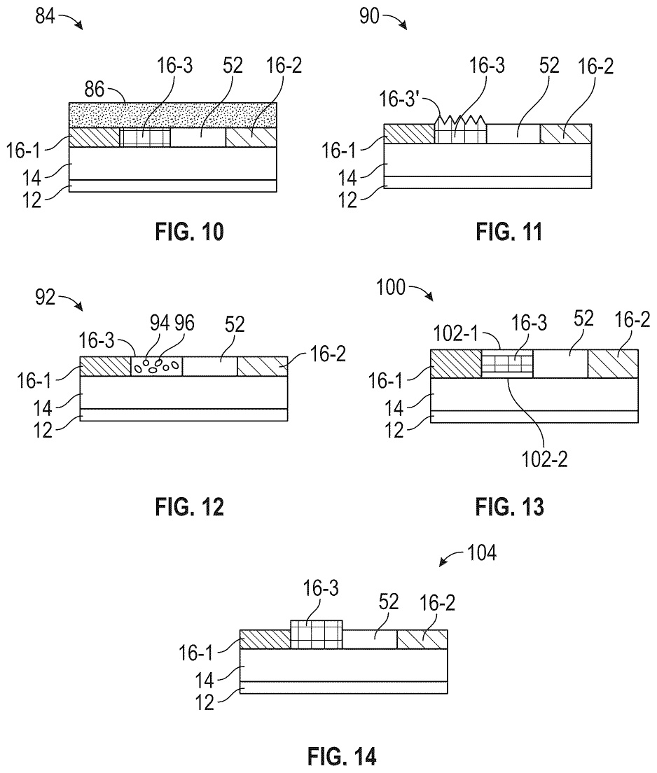

FIG. 10 is a side view of an LED chip 84 similar to the LED chip 10 of FIGS. 1A to 1E for embodiments that further include a cover structure 86. In certain embodiments, the cover structure 86 may embody a light-transparent cover structure, such as glass or silicone, that effectively covers and protects the underlying wavelength conversion elements 16-1 to 16-3. In further embodiments, the cover structure 86 may comprise a light-scattering cover structure configured to scatter and/or diffuse light from the LED chip 84. In FIG. 10, the cover structure 86 is positioned on the wavelength conversion elements 16-1 to 16-3 and the encapsulant structure 52, thereby forming a light emission surface for the LED chip 84. The cover structure 86 may embody a coating with light-scattering materials and/or particles that is formed on the LED chip 84. Alternatively, the cover structure 86 may embody a pre-formed structure including light-scattering materials and/or particles that is subsequently attached to the LED chip 84.

FIG. 11 is a side view of an LED chip 90 similar to the LED chip 10 of FIGS. 1A to 1E for embodiments where at least one of the wavelength conversion elements 16-1 to 16-3 comprises a nonplanar surface. For example, the wavelength conversion element 16-3 may be formed with a patterned or randomly textured surface 16-3′ in order to alter emission patterns of light exiting the wavelength conversion element 16-3. Accordingly, light from the wavelength conversion element 16-3 may be tailored to have a wider emission pattern for improved mixing of light from the other wavelength conversion elements 16-1, 16-2 and/or the encapsulant structure 52.

FIG. 12 is a side view of an LED chip 92 similar to the LED chip 10 of FIGS. 1A to 1E for embodiments where at least one wavelength conversion elements 16-3 comprises light-scattering particles 94 mixed with lumiphoric material particles 96. While lumiphoric material particles 96 may scatter light, a material of the wavelength conversion element 16-3 may additionally comprise light-scattering particles 94 to further enhance light scattering and color mixing of light from the wavelength conversion element 16-3. The light-scattering particles 94 are configured to scatter light without performing wavelength conversion. For illustrative purposes, the lumiphoric material particles 96 are generally drawn in the wavelength conversion element 16-3 for the purposes of showing a mixture of the light scattering particles 94 and lumiphoric material particles 96. It is understood that all of the wavelength conversion elements for all of embodiments of the present disclosure, including FIGS. 1A to 11, 13, and 14, may also include lumiphoric material particles 96 as illustrated for FIG. 12.

FIG. 13 is a side view of an LED chip 100 similar to the LED chip 92 of FIG. 12 for embodiments where at least one wavelength conversion element 16-3 includes at least one light-scattering coating 102-1, 102-2. Instead of mixing light-scattering particles 94 with the lumiphoric material particles 96 as illustrated by FIG. 12, the wavelength conversion element 16-3 may comprise a light-scattering coating 102-1 formed on a surface thereof. In one example, the light-scattering coating 102-1 is on a side of the wavelength conversion element 16-3 opposite the active LED structure 12. In further embodiments, light-scattering coatings 102-1, 102-2 are positioned on both sides of the wavelength conversion element 16-3.

FIG. 14 is a side view of an LED chip 104 similar to the LED chip 10 of FIGS. 1A to 1E for embodiments where at least one wavelength conversion elements 16-3 comprises a different thickness than the other wavelength conversion elements 16-1, 16-2. Since the wavelength conversion elements 16-1 to 16-3 may be separately formed relative to one another, relative thicknesses may be varied to further tune targeted color mixing in aggregate emissions.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip, comprising:
an active LED structure comprising an n-type layer, a p-type layer, and an active layer that is between the n-type layer and the p-type layer;
a first wavelength conversion element on a first region of the active LED structure;
a second wavelength conversion element on a second region of the active LED structure, the active LED structure being continuous between the first region and the second region;
a first p-contact on the first region of the active LED structure;
a second p-contact on the second region of the active LED structure; and
an n-contact on both the first region and the second region of the active LED structure.

2. The LED chip of claim 1, wherein the first p-contact and the n-contact are configured to inject current directly into the first region and indirectly into the second region, and the second p-contact and the n-contact are configured to inject current directly into the second region and indirectly into the first region.

3. The LED chip of claim 2, further comprising:
a third wavelength conversion element on a third region of the active LED structure, the active LED structure being continuous between the first region, the second region, and the third region; and
a third p-contact on the third region, the third p-contact and the n-contact being configured to inject current directly into the third region.

4. The LED chip of claim 3, further comprising:
a fourth wavelength conversion element on a fourth region of the active LED structure, the active LED structure being continuous between the first region, the second region, the third region, and the fourth region; and
a fourth p-contact on the fourth region, the fourth p-contact and the n-contact being configured to inject current directly into the fourth region;
wherein the first wavelength conversion element, the second wavelength conversion element, the third wavelength conversion element, and the fourth wavelength conversion element are configured to provide aggregate emissions with five distinct peak wavelengths.

5. The LED chip of claim 1, wherein at least one portion of the active LED structure in the first region is devoid of any wavelength conversion element.

6. The LED chip of claim 5, wherein the at least one portion of the active LED structure is covered by an encapsulant structure that is transparent to light emitted by the active LED structure.

7. The LED chip of claim 1, further comprising a light-absorbing material positioned between the first wavelength conversion element and the second wavelength conversion element.

8. The LED chip of claim 1, further comprising a light-reflective material positioned between the first wavelength conversion element and the second wavelength conversion element.

9. The LED chip of claim 1, further comprising a substrate on which the active LED structure is supported, wherein the first wavelength conversion element and the second wavelength conversion element are on a side of the substrate opposite the active LED structure.

10. The LED chip of claim 1, further comprising a carrier submount on which the active LED structure is supported, wherein the first p-contact is on an opposite side of the carrier submount relative to the n-contact.

11. The LED chip of claim 1, wherein an area of the first wavelength conversion element on the active LED structure is less than an area of the second wavelength conversion element on the active LED structure.

12. The LED chip of claim 1, further comprising a light-scattering cover structure on the first wavelength conversion element and on the second wavelength conversion element.

13. The LED chip of claim 1, wherein the first wavelength conversion element comprises a patterned or a textured surface.

14. The LED chip of claim 1, wherein the first wavelength conversion element comprises a mixture of light-scattering particles and lumiphoric material particles.

15. The LED chip of claim 1, wherein the first wavelength conversion element comprises at least one light-scattering coating.

16. The LED chip of claim 1, wherein the first wavelength conversion element comprises a different thickness than the second wavelength conversion element.

17. A light-emitting diode (LED) chip, comprising:
an active LED structure comprising an n-type layer, a p-type layer, and an active layer that is between the n-type layer and the p-type layer;
a plurality of first wavelength conversion elements on the active LED structure;
a first p-contact on a first region of the active LED structure;
a second p-contact on a second region of the active LED structure, the active LED structure being continuous between the first region and the second region, and the plurality of first wavelength conversion elements being positioned on both the first region and the second region; and
an n-contact on both the first region and the second region of the active LED structure.

18. The LED chip of claim 17, wherein the first p-contact and the n-contact are configured to inject current directly into the first region and indirectly into the second region, and the second p-contact and the n-contact are configured to inject current directly into the second region and indirectly into the first region.

19. The LED chip of claim 17, wherein each first wavelength conversion element of the plurality of first wavelength conversion elements is configured to convert a first peak wavelength of light from the active LED structure to a second peak wavelength that is different than the first peak wavelength.

20. The LED chip of claim 19, further comprising a plurality of second wavelength conversion elements on both the first region and the second region of the active LED structure, wherein each second wavelength conversion element of the plurality of second wavelength conversion elements is configured to convert the first peak wavelength of light from the active LED structure to a third peak wavelength that is different than the first peak wavelength and the second peak wavelength.
